(19) United States
(12) Patent Application Publication
(10) Pub. No.: US 2006/0220761 A1
(43) Pub. Date: Oct. 5, 2006

(54) Distributed constant circuit and impedance adjustment method

(75) Inventor: Hiroshi Ikeda, Tokyo (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: TDK CORPORATION, Chuo-ku (JP)

(21) Appl. No.: 11/373,095

(22) Filed: Mar. 13, 2006

(30) Foreign Application Priority Data
Mar. 31, 2005 (JP) 2005-104685

(51) Int. Cl. H03H 7/38

(52) U.S. Cl. 333/33

(57) ABSTRACT

According to a conventional art, a large number of adjustment pads are necessary if impedance mismatching is large or characteristic impedance is low. Such a large number of the adjustment pads needs to secure a large area for arrangement of the adjustment pads preliminarily. However, occupation of a large area induces an interference with other distributed constant circuit. The present invention concerns a distributed constant circuit capable of adjusting the impedance matching between a conductor line such as micro strip line disposed in a small area and an electronic device in order to solve the above-described problems. This distributed constant circuit intends to achieve the impedance matching between the characteristic impedance of the conductor line and the load impedance or drive impedance of the electronic device by bringing the adjustment tab moving on a substrate into a contact with the conductor line.

### BACKGROUND OF THE INVENTION

1. Field of the Invention

The present invention relates to a distributed constant circuit capable of achieving impedance matching between a conductor line provided on the top face of a substrate and an electronic device connected to an input terminal or an output terminal and a method of adjusting the impedance matching of the distributed constant circuit.

2. Description of the Related Art

When a conductor line or an electronic device connected to the conductor line is constituted on a substrate, sometimes impedance matching cannot be achieved between the characteristic impedance of the conductor line and load impedance or drive impedance of an electronic device. As causes for impedance mismatching, dispersion of dielectric constant or loss angle of substrate material, dielectric constant of conductive material of conductor line or length in minor axis thereof, dispersion of thickness of the conductor line, dispersion of impedance of electronic device such as semiconductor device and the like can be considered.

In order to adjust for such impedance mismatching, conventionally, a technology of forming a plurality of adjustment pads on the side of a conductor line has been available. FIG. 1 shows a distributed constant circuit in which the adjustment pads are formed. Referring to FIG. 1, reference numeral 10 denotes a substrate, reference numerals 11, 12 denote a micro strip line, reference numeral 15 denotes an input terminal to the micro strip line 11, reference numeral 16 denotes an output terminal from a micro strip line 12, reference numeral 17 denotes a ground, reference numeral 21 denotes a semiconductor device, reference numerals 51, 52 denote adjustment pads and reference numeral 500 denotes a distributed constant circuit.

The micro strip lines 11, 12 are designed so as to have an inherent characteristic impedance. Further, the semiconductor device 21 is designed so as to have inherent load impedance on the input side of the semiconductor device 21 and an inherent drive impedance on the output side. Usually, the characteristic impedance of the micro strip line 11 and the load impedance of the semiconductor 21 are set up to match each other and the characteristic impedance of the micro strip line 12 and the drive impedance of the semiconductor device 21 are set up to match each other.

However, because impedance mismatching occurs due to the above-described reasons, the micro strip line 11 and the adjustment pad 51 are connected with metal wire, solder and metal plate so as to achieve matching between the characteristic impedance of the micro strip 11 and the load impedance of the semiconductor device 21 and then, the micro strip line 12 and the adjustment pads 52 are connected so as to achieve matching between the characteristic impedance of the micro strip line 12 and the drive impedance of the semiconductor device 21.

Additionally, technology of achieving impedance matching using a spherical conductor on the micro strip line having a rail-like groove has been proposed (see, for example, Japanese Patent Application Laid-Open No. 9-252207). This is to adjust impedance matching between the characteristic impedance of the micro strip line and the input/output impedance by moving the spherical conductor on the rail-like groove.

The conventional art described in FIG. 1 needs a large number of adjustment pads if the impedance mismatching is large or the characteristic impedance is low. The large number of the adjustment pads requires a wide area for arrangement of the adjustment pads preliminarily. Occupation of a wide area increases the size of the distributed constant circuit. Further, interference with other distributed constant circuit is generated. Further, because the adjustment pad and the micro strip line are coupled even when they are not connected with any metal wire or the like, the characteristic impedance becomes different from that of a single unit micro strip line only by disposing the adjustment pads.

Although the art described in Japanese Patent Application Laid-Open No. 9-252207 requires the rail-like groove to be formed on the substrate, a high level processing technology is needed to form the rail-like groove on a resin substrate used as the material of the substrate. Further, because the contact point of the rail-like groove and the spherical conductor is small, stability of connection is low so that it is difficult to adjust the impedance matching.

### SUMMARY OF THE INVENTION

To solve the above-described problems, an object of the present invention is to provide a distributed constant circuit capable of adjusting the impedance matching between the conductor line such as the micro strip line and an electronic device easily, disposed in a small area.

According to the present invention, the impedance matching between the characteristic impedance of the conductor line and the load impedance or drive impedance of an electronic device is achieved by bringing the adjustment tab moving on the substrate into a contact with the conductor line.

More specifically, the present invention provides a distributed constant circuit including: a substrate composed of dielectric material; a conductor line provided on the top face of the substrate; an electronic device connected to the conductor line; and an adjustment tab composed of a flat conductor in contact with the conductor line.

As a consequence, the present invention enables to adjust the impedance matching between the characteristic impedance of the conductor line and the load impedance or drive impedance of an electronic device easily by moving the adjustment tab into a contact with the conductor line even if there is only a small area on the substrate. Further, the adjustment tab can be removed, so that the characteristic of the conductor line can be provided only by removing it.

Preferably, a portion projecting from the conductor line of the adjustment tab is chamfered.

The inventor has clarified that electric field is concentrated on the corners of the adjustment tab by simulation. If electric field is concentrated, a slight change of position of the adjustment tab fluctuates the impedance characteristic largely. If the corners are chamfered, concentration of electric field can be prevented so as to adjust the impedance matching easily.

According to another aspect of the present invention, there is provided a distributed constant circuit including: a substrate composed of dielectric material; a conductor line provided on the top face of the substrate and having a projecting portion on the substrate face; and an electronic device connected to the conductor line, wherein the projecting portion is chamfered.

The projecting portion can provide a distributed constant circuit which secures impedance matching between the characteristic impedance of the conductor line and the load impedance or drive impedance of an electronic device. Because this projecting portion is chamfered, it can prevent concentration of electric field and even if the distributed constant circuit is installed in a case or the like, an influence on the distribution of electric field by the case is small.

According to still another aspect of the present invention, there is provided an impedance adjustment method of adjusting impedance matching between the conductor line and an electronic device connected to the conductor line by moving an adjustment tab composed of conductor in the direction of major axis or minor axis of the conductor line to bring the adjustment tab into a contact with the conductor line provided on the top face of the substrate composed of dielectric material.

According to the present invention, the impedance matching between the characteristic impedance of the conductor line and the load impedance or drive impedance of an electronic device can be adjusted easily by moving the adjustment tab in the direction of major axis or minor axis of the conductor line into a contact with the conductor line even if there is the only a small area on the substrate. Further, the adjustment tab may be removed and the characteristic of the conductor line can be provided only by removing it.

In this application, the propagation direction of a signal through the conducive conductor line is referred to as direction of major axis and a direction perpendicular to the direction of major axis is referred to as direction of minor axis.

Accordingly, the present invention can provide a distributed constant circuit and impedance adjustment method capable of adjusting the impedance matching between the characteristic impedance of the conductor line and the load impedance or drive impedance of an electronic device easily.

### BRIEF DESCRIPTION OF THE DRAWINGS

FIG. 1 is a structure drawing for explaining an example of a conventional distributed constant circuit;

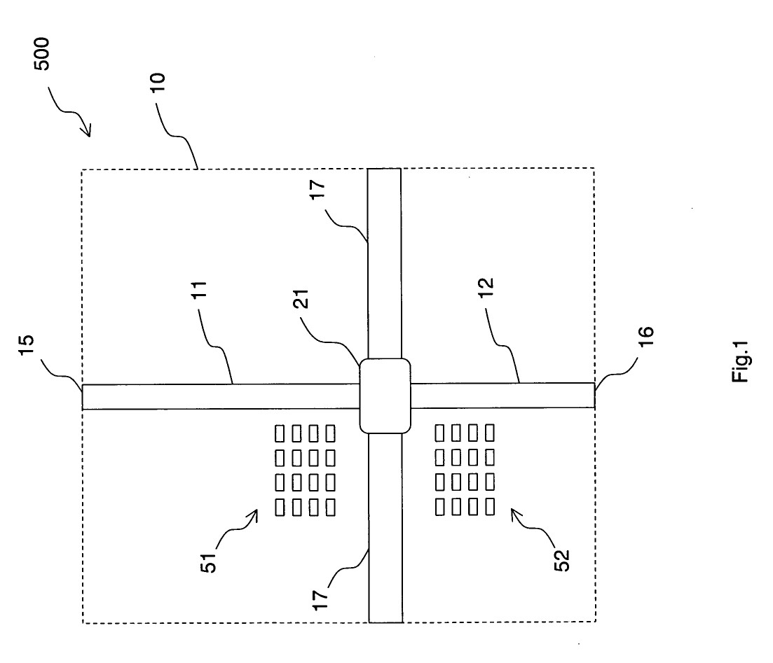

FIG. 2 is a structure drawing for explaining an example of the embodiment of the distributed constant circuit according to the present invention;

FIG. 3 is a diagram for explaining a method of achieving the impedance matching with an adjustment tab in contact with the micro strip line;

FIG. 4 is a structure drawing for explaining an example of the embodiment of the distributed constant circuit according to the present invention; and

FIG. 5 is a structure drawing for explaining an example of the embodiment of the distributed constant circuit according to the present invention.

### DESCRIPTION OF THE PREFERRED EMBODIMENTS

Hereinafter, the preferred embodiment of the present invention will be described with reference to the accompanying drawings. However, the present invention is not restricted to embodiments described below.

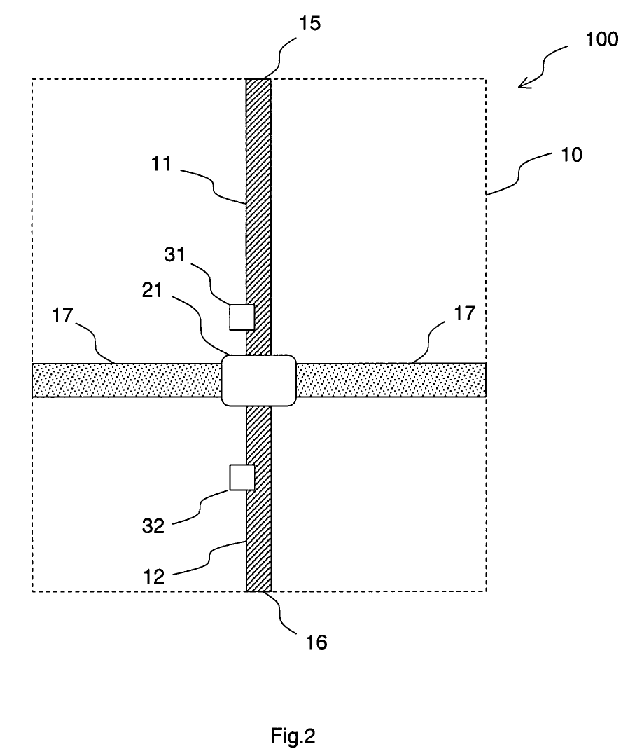

FIG. 2 is a structure drawing for explaining an example of the embodiment of the distributed constant circuit of the present invention. Referring to FIG. 2, reference numeral 10 denotes a substrate, reference numerals 11, 12 denote a micro strip line provided on the top face of the substrate 10, reference numeral 15 denotes an input terminal to the micro strip line 11, reference numeral 16 denotes an output terminal from the micro strip line 12, reference numeral 17 denotes a ground, reference numeral 21 denotes a semiconductor device as an electronic device, reference numerals 31, 32 denote a flat adjustment tab composed of conductor and reference numeral 100 denotes a distributed constant circuit.

The micro strip line is constituted of a ground formed on a single face of the substrate composed of dielectric material and a conductor line as a distributed constant line formed on the other side. The characteristic impedance of the micro strip line is determined depending on the thickness of the conductor line, the length in the minor axis of the conductor line, the thickness of the substrate, and dielectric constant of a dielectric material constituting the substrate. These constants which determine the characteristic impedance become different values from their design values if manufacturing deviation is added to these values. Further, the characteristic impedance of the micro strip line fluctuates if the distributed constant circuit is stored into a case or a connector for input or output is attached.

On the other hand, the load impedance and drive impedance of an electronic circuit can be different from a design value due to manufacturing deviation. Further, the frequency characteristic is generated depending on floating capacitance or floating inductance so that a design load impedance or drive impedance cannot be achieved depending on which frequency band to be applied.

In FIG. 2, if the characteristic impedance of the micro strip line 11 is different from the load impedance of the semiconductor device 21 when a signal inputted from the input terminal 15 propagated through the micro strip line 11 and enters the semiconductor device 21, reflection occurs or a proper signal amplitude cannot be obtained due to impedance mismatching.

Then, the adjustment tab 31 is brought into a contact with the micro strip line 11. Here, if the characteristic impedance of the micro strip line 11 matches the load impedance of the semiconductor device 21, the micro strip line 11 and the adjustment tab 31 are fixed. It is desirable to use solder or conductive adhesive agent for this fixing. As a consequence, electric connection between the micro strip line 11 and the adjustment tab 31 can be carried out securely thereby preventing the adjustment tab from moving carelessly.

Unless the characteristic impedance of the micro strip line 11 matches the load impedance of the semiconductor device 21, the adjustment tab 31 is moved. The moving direction is in the major axis or minor axis of the micro strip line 11. This may be oblique to the major axis of the micro strip line 11 by summing up the moves in the major direction and minor direction. The adjustment tab 31 may be moved in a condition in contact with the micro strip line 11. If it is moved in the condition in contact with the micro strip line 11, whether or not impedance matching is achieved during that moving can be evaluated. It is convenient to use a pair of tweezers for holding a tip of the dielectric material upon moving. By matching the characteristic impedance of the micro strip line 11 with the load impedance of the semiconductor 21, the micro strip line 11 and the adjustment tab 31 are fixed.

If the impedance characteristic changes when the micro strip line 11 and the adjustment tab 31 are fixed, whether or not the impedance matching is secured after the fixing is evaluated. If it is determined that the impedance matching after the fixing is insufficient, the adjustment tab 31 is separated from the micro strip line 11 and by moving the adjustment tab 31 again, it is brought into a contact with the micro strip line 11. If solder is used for fixing the micro strip line 11 and the adjustment tab 31, the adjustment tab 31 can be separated from the micro strip line 11 by heating solder.

In FIG. 2, impedance matching between the characteristic impedance of the micro strip line 12 and the drive impedance of the semiconductor device 21 can be carried out in the same operation. This impedance matching can be adjusted by moving the adjustment tab 32 into a contact with the micro strip line 12.

Although the semiconductor device 21 is exemplified in FIG. 2 as the electric device, it is permissible to combine a passive device or other semiconductor device as the electronic device. Although an adjustment tab is disposed for each micro strip, it is permissible to use a plurality of the adjustment tabs. Although the ground 17 is provided on each of both sides of the semiconductor device 21, this may be provided on only one side or conductive with an opposite side through a via hole.

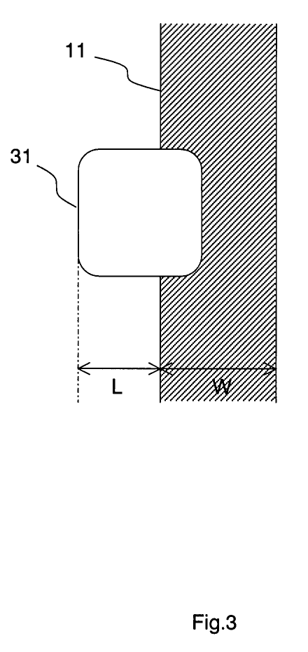

Adjustment of the impedance matching will be described with reference to FIG. 3. The same reference numeral as in FIG. 2 means the same component. W denotes the length of the minor axis of the micro strip line 11 and L denotes the length in the minor axis direction of the micro strip line 11 of a portion projecting from the micro strip line 11, that is to say, as shown in FIG. 3, the length of the portion projecting from the micro strip line 11 of the adjustment tab 31 from the side end of the micro strip line 11 up to the front end of the adjustment tab 31 (hereinafter this length is abbreviated as “length of the projecting portion of the adjustment tab”).

Although the shape of the adjustment tab is a rounded corner square in FIG. 3, the present invention is not restricted to this shape. This may be circular, elliptic, rectangular or polygon or the like.

To achieve impedance matching with the adjustment tab 31 kept in contact with the micro strip line 11 in FIG. 3, it is preferable that L≦W. Because the micro strip line is designed for TEM mode propagation, usually, the length W of the minor axis of the micro strip line is set to equal to or less than ⅛ a wavelength of the frequency to be propagated. If the sum of the length W of the minor axis of the micro strip line and the length L of a projecting portion of the adjustment tab is ¼ the wavelength of the frequency of a signal to be propagated by bringing the adjustment tab into contact with the micro strip line, a standing wave can be generated in the direction of the minor axis of the micro strip line and at a portion of the adjustment tab. If the standing wave is generated, resonance occurs so that the propagation characteristic is damped largely, the phase is shifted or the characteristic impedance fluctuates largely. Thus, it is preferable that L≦W.

A portion projecting from the micro strip line 11 of the adjustment tab 31 is preferred to be chamfered. The adjustment tab is chamfered so as to have no sharp angle. Although it may be chamfered linearly or circularly, the present invention is not restricted to these shapes.

When this inventor have adjusted the impedance matching using the adjustment tab not chamfered, the characteristic was changed largely only by moving the adjustment tab slightly. As a result of simulating the electric field intensity to search for this reason, it was made evident that electric field was concentrated to the angle of the adjustment tab. That is, when a portion on which the electric field is concentrated, the characteristic is changed drastically. As a result of chamfering the corners of the adjustment tab, concentration of the electric field could be prevented and when the adjustment tab have been moved, the impedance matching could be adjusted easily without a drastic change of the impedance characteristic.

Even if the distributed constant circuit is accommodated in a case or the like, chamfering the corner of the adjustment tab reduces an influence on the distribution of the electric field by the case, thereby achieving stable impedance matching.

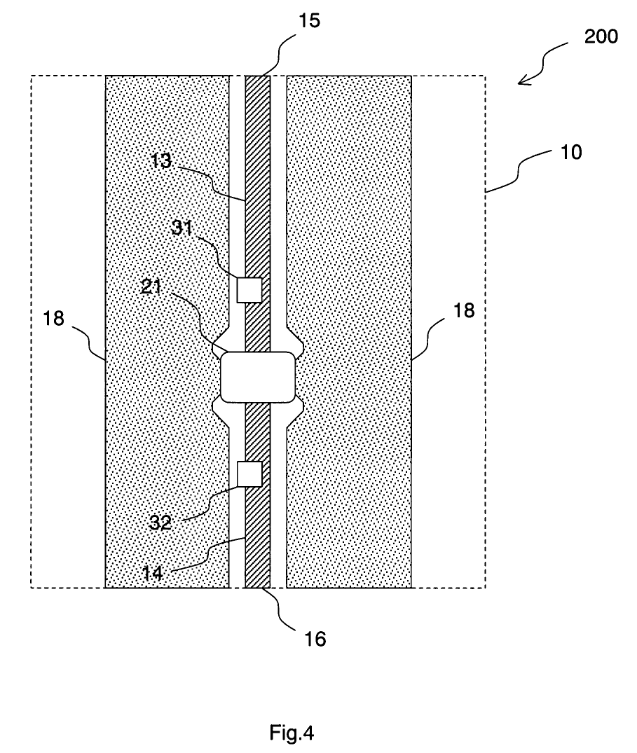

FIG. 4 is a structure drawing for explaining an example of other embodiment of the distributed constant circuit of the present invention. Referring to FIG. 4, reference numeral 10 denotes a substrate composed of dielectric material, reference numerals 13, 14 denote a coplanar line provided on the top face of the substrate 10 as a conductor line, reference numeral 15 denotes an input terminal to the coplanar line 13, reference numeral 16 denotes an output terminal from the coplanar line 14, reference numeral 18 denotes a ground face, reference numeral 21 denotes a semiconductor device as an electronic device, reference numerals 31, 32 denote a flat adjustment tab composed of conductor and reference numeral 200 denotes a distributed constant circuit.

The coplanar line is constituted of conductor lines formed on one face of the substrate from dielectric material and ground faces formed on both sides of conductor lines. The characteristic impedance of the coplanar line is determined depending on the thickness of the conductor line, the length in the minor axis of the conductor line, the gap between the conductor line and ground, the thickness of the substrate and the dielectric constant of the dielectric material constituting the substrate. If manufacturing deviation is added to these constants which determine the characteristic impedance, they become different values from their design values. Further, if the distributed constant circuit is accommodated in a case or a connector for input/output is attached, the characteristic impedance of the coplanar line fluctuates.

On the other hand, the load impedance and drive impedance of an electronic circuit can be different from their design values because of manufacturing deviation. Further, the frequency characteristic is generated depending on floating capacitance or floating inductance so that a design load impedance or drive impedance cannot be achieved depending on which frequency band to be applied.

In FIG. 4, if a signal inputted from the input terminal 15 propagates through the coplanar line 13 and when it enters the semiconductor device 21, the characteristic impedance of the coplanar line 13 is different from the load impedance of the semiconductor 21, reflection occurs due to the impedance mismatching or no proper signal amplitude can be obtained.

Then, the adjustment tab 31 is brought into a contact with the coplanar line 13. By matching the characteristic impedance of the coplanar line 13 with the load impedance of the semiconductor device 21, the coplanar line 13 and the adjustment tab 31 are fixed. It is preferable to use solder or conductive adhesive agent for the fixing. As a result, the coplanar line 13 and the adjustment tab 31 can be connected electrically securely and additionally the adjustment tab can be prevented from being moved carelessly.

The method of adjusting the impedance adjustment using the adjustment tab 31 is the same as the case of the micro strip line. The impedance matching between the characteristic impedance of the coplanar line 14 and the drive impedance of the electronic device 21 using the adjustment tab 32 is the same as in the case of the micro strip line. Because in the case of the coplanar line, the ground face is close to the coplanar line, the impedance matching is changed largely only by a slight adjustment as compared with the case of the micro strip line.

Although use of the adjustment pad described in the conventional technique is difficult in case of the coplanar line, the adjustment tab of the present invention can be disposed in a small area so that the impedance matching can be adjusted easily.

The length of the projecting portion of the adjusting tab and the shape of the projecting portion of the adjustment tab are the same as described in FIG. 3.

As described above, the distributed constant circuit of the embodiment of the present invention can achieve the impedance matching between the electronic device and the conductor line by bringing the adjustment tab composed of a movable conductor into a contact with the conductor line.

Therefore, the impedance matching can be adjusted easily even if an electronic device is disposed in a small area and if the adjustment of the impedance matching is unnecessary, the characteristic of the conductor line can be provided only by removing the adjustment tab. Further, by fixing the adjustment tab to the conductor line, the impedance matching can be secured stably.

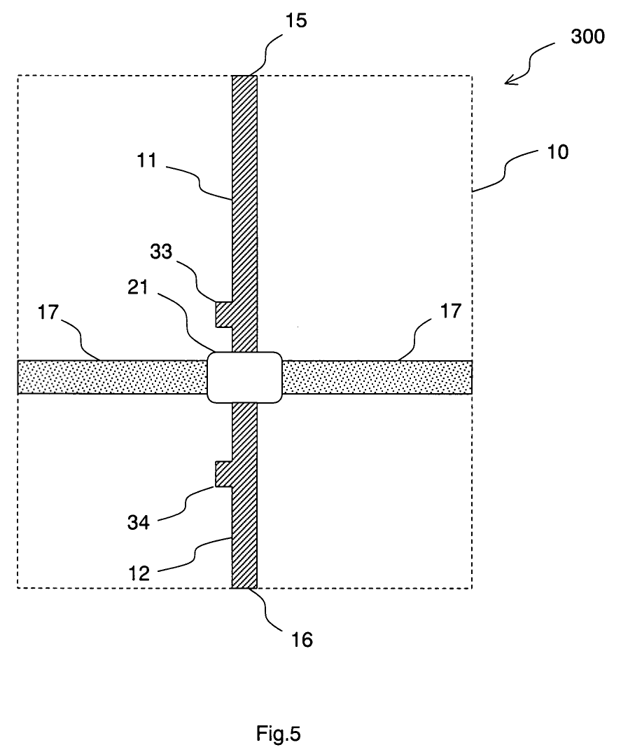

If the distributed constant circuit is mass produced, a pattern in which the adjustment tab when the impedance matching is secured according to the above described embodiment is overlapped on the conductor line is produced as a new conductor line pattern. FIG. 5 shows an example of the distributed constant circuit in which the pattern produced by overlapping the adjustment tab described previously in FIG. 5 on the conductor line is uses as a new conductor line pattern. In FIG. 5, the same reference numeral as in FIG. 2 indicates the same meaning. Reference numerals 33, 34 denote a projecting portion and reference numeral 300 denotes a distributed constant circuit.

This indicates an example in which the pattern produced by overlapping the adjustment tab described in FIG. 2 on the micro strip line is employed as a new micro strip line pattern. The distributed constant circuit provided with such a micro strip line comes to achieve the impedance matching between the characteristic impedance of the micro strip line and the load impedance or drive impedance of the electronic device after it is manufactured.

Because the projecting portions 33, 34 are chamfered, concentration of electric field can be prevented and even if the distributed constant circuit 100 is installed in a case or the like, an influence upon the distribution of electric field is small. Because the length of a portion of the projecting portion 33, 34, which projects from the micro strip line 11 or 12 in the direction of the minor axis of the micro strip line 11 or 12, is equal to or shorter than the length in the direction of the minor axis of the micro strip line 11 or 12, generation of standing wave in the direction of the minor axis of the micro strip line 11 or 12 can be prevented.

As for the coplanar line described in FIG. 4, if a pattern in which the adjustment tab is overlapped on the coplanar line is employed as a new coplanar line pattern, the same effect can be obtained. The distributed constant circuit having such a coplanar line can secure the impedance matching between the characteristic impedance of the coplanar line and the load impedance or drive impedance of an electronic device after it is manufactured.

The distributed constant circuit and impedance adjustment method of the present invention can be applied for a radio device using high frequency, an amplifier of coaxial CATV using carrier wave and adjustment thereof.

What is claimed is:

1. A distributed constant circuit comprising:
a substrate composed of dielectric material;
a conductor line provided on the top face of the substrate;
an electronic device connected to the conductor line; and
an adjustment tab composed of a flat conductor in contact with the conductor line.

2. The distributed constant circuit according to claim 1, wherein a portion projecting from the conductor line of the adjustment tab is chamfered.

3. A distributed constant circuit comprising:
a substrate composed of dielectric material;
a conductor line provided on the top face of the substrate and having a projecting portion on the substrate face; and
an electronic device connected to the conductor line, wherein the projecting portion is chamfered.

4. An impedance adjustment method of adjusting impedance matching between the conductor line and an electronic device connected to the conductor line by moving an adjustment tab composed of conductor in the direction of major axis or minor axis of the conductor line to bring the adjustment tab into a contact with the conductor line provided on the top face of the substrate composed of dielectric material.
